(19) United States
(12) Patent Application Publication
(10) Pub. No.: US 2021/0210339 A1
(43) Pub. Date: Jul. 8, 2021

(54) CONFORMAL HERMETIC FILM DEPOSITION BY CVD

(71) Applicant: APPLIED MATERIALS, INC., Santa Clara, CA (US)

(72) Inventors: Pramit MANNA, Sunnyvale, CA (US); Rui CHENG, San Jose, CA (US); Abhijit Basu MALLICK, Fremont, CA (US); Shishi JIANG, Santa Clara, CA (US)

(73) Assignee: Applied Materials, Inc., Santa Clara, CA (US)

(21) Appl. No.: 15/778,167

(22) PCT Filed: Dec. 20, 2017
(86) PCT No.: PCT/US2017/067682

§ 371 Date: May 22, 2018

Related U.S. Application Data
(60) Provisional application No. 62/485,689, filed on Apr. 14, 2017.
(60) Provisional application No. 62/437,487, filed on Dec. 21, 2016.

(51) Int. Cl. H01L 21/02

(52) U.S. Cl. CPC H01L 21/0217; H01L 21/02274; H01L 21/0228

(57) ABSTRACT

A method for forming a conformal hermetic silicon nitride film. The method includes using thermal chemical vapor deposition with a polysilane gas to produce an ultra-conformal amorphous silicon film on a substrate, then treating the film with ammonia or nitrogen plasmas to convert the amorphous silicon film to a conformal hermetic silicon nitride. In some embodiments, the amorphous silicon deposition and the plasma treatment are performed in the same processing chamber. In some embodiments, the amorphous silicon deposition and the plasma treatment are repeated until a desired silicon nitride film thickness is reached.

### BACKGROUND

### Field

Embodiments of the present disclosure generally relate to methods used in the manufacturing of semiconductor devices, in particular to methods of forming ultra-conformal hermetic silicon nitride films, using thermal chemical vapor deposition (CVD) and plasma treatment, in a substrate processing chamber.

### Description of the Related Art

Silicon nitride films are used as dielectric materials in semiconductor devices as, for example, insulator layers between metal levels and barrier layers between different types of material layers to prevent oxidation or atomic diffusion in multi-level interconnections, hard masks, passivation layers, spacer materials, transistor gate electrode structures, anti-reflective coating materials, non-volatile memories layers, and other applications. Hermetic silicon nitride films can be used as a protective coating to prevent oxidation of an underlying layer, such as an amorphous silicon layer, during high temperature annealing thereof. Atomic layer deposition, using chlorosilane and ammonia precursors at temperatures greater than 400 degrees Celsius, is one method used to deposit a silicon nitride film. However, this combination of precursors reacts to produce hydrochloric acid and/or ammonium chloride byproducts that are undesirable because of their corrosive effect on previously formed material layers on the substrate.

Batch reactors have been used to form silicon nitride films by a thermal CVD process to form a silicon layer on a substrate, for example on a film layer previously formed on the substrate, followed by plasma nitridation thereof to convert the silicon layer to a silicon nitride layer. However, the uneven distribution of deposition precursors reaching the substrate inherent in batch processes often results in a non-uniform thickness of the deposited silicon layer. Moreover, uneven plasma distribution may result in a non-uniform nitridation depth into the deposited silicon layer across the span of the silicon layer. The combination of non-uniform silicon thickness and non-uniform nitridation depth often results in undesirable nitrogen diffusion through the deposited silicon layer and into the substrate in some areas and incomplete nitridation of the silicon layer in other areas. Undesirable nitrogen diffusion through the deposited silicon layer and into the underlying material reduces the effectiveness of the silicon nitride film as a dielectric and can change the properties of the underlying material.

Therefore, there is a need in the art for a method of forming ultra-conformal hermetic silicon nitride and silicon nitride like films at low deposition temperatures, without generating hydrochloric acid or ammonium chloride byproducts, and extremely uniform composition and thickness.

### SUMMARY

Embodiments of the present disclosure generally relate to methods used in the manufacturing of semiconductor devices in particular, to methods of forming ultra-conformal hermetic silicon nitride films, using thermal chemical vapor deposition (CVD) and plasma treatment, in a substrate processing chamber.

In one embodiment, a method of forming a film layer is provided. The method includes heating a substrate to a substrate temperature within a substrate processing chamber, flowing a silicon precursor gas into the substrate processing chamber, depositing a layer of amorphous silicon on the substrate, flowing a nitrogen precursor gas into the substrate processing chamber, forming a plasma within the substrate processing chamber with the nitrogen precursor gas, and exposing the deposited amorphous silicon layer to the plasma to convert at least a portion of the deposited amorphous silicon layer to a silicon nitride layer.

In another embodiment, a method of forming a film layer is provided. The method includes heating a substrate, disposed on a substrate support, to a temperature of below about 500° C. within a substrate processing chamber. The method further includes flowing a silicon precursor gas into the substrate processing chamber. The method further includes depositing a layer of amorphous silicon on the substrate. The method further includes flowing a nitrogen precursor gas into the substrate processing chamber, where the nitrogen precursor gas comprises N2, NH3, H2N2, or a combination thereof and forming a plasma of the nitrogen precursor gas within the substrate processing chamber. The method further includes biasing a first electrode coupled to the substrate support, wherein the first electrode is coupled to a first resonant tuning circuit and dynamically adjusting the impedance of the first resonant tuning circuit to control the current flow through the first electrode, where the current flow is desirably maintained at a set point between about 1 amp and 30 amps. The method further includes nitriding the deposited amorphous silicon layer to convert the deposited amorphous silicon layer to a silicon nitride layer.

In another embodiment, a method of forming a film layer is provided. The method includes heating a substrate to a substrate temperature of below about 500° C., flowing a silicon precursor gas into a substrate processing chamber, and depositing a film of amorphous silicon on the substrate of between about 5 Å and about 30 Å. The method further includes flowing a nitrogen precursor gas into the substrate processing chamber, where the nitrogen precursor gas comprises N2, NH3, H2N2, or a combination thereof and forming a plasma with the nitrogen precursor gas, where the plasma is formed within the processing chamber. The method further includes biasing a first electrode coupled to a substrate support, where the first electrode is coupled to a first resonant tuning circuit and dynamically adjusting the impedance of the first resonant tuning circuit to control the current flow through the first electrode, where the current flow is desirably maintained at a set point between about 1 amp and 30 amps. The method further includes biasing a second electrode coupled to a side wall of the chamber, where the second electrode is coupled to a second resonant tuning circuit and dynamically adjusting the impedance of the second resonant tuning circuit to control the current flow through the second electrode, where the current flow is desirably maintained at a set point between about 1 amp and 30 amps. The method further includes converting the deposited amorphous silicon film to a hermetic stoichiometric silicon nitride film.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of one embodiment of a processing chamber that may be used to practice the methods described herein.

FIG. 2 is a schematic cross-sectional view of one embodiment of a substrate support that may be used to practice the methods described herein.

FIG. 3 is a flow diagram of a method for depositing a silicon nitride film, according to one embodiment.

### DETAILED DESCRIPTION

Embodiments of the present disclosure generally relate to methods used in the manufacturing of semiconductor devices in particular, to methods of forming ultra-conformal hermetic silicon nitride films using thermal chemical vapor deposition (CVD) and plasma treatment in a substrate processing chamber.

Herein, extremely uniform silicon nitride film layers are formed on a substrate using thermal CVD to deposit amorphous silicon followed by plasma nitridation. Uniformity of the film layer composition and thickness is achieved by controlling gas flow uniformity, temperature uniformity of the surfaces of the processing chamber, the temperature profile across the substrate, and the plasma density profile at various locations across the substrate surface. In some embodiments, the temperature profile across the substrate is adjusted to achieve a desired silicon deposition rate profile across the substrate surface. In some embodiments, the plasma density profile and the temperature profile are adjusted together to achieve a uniform nitridation depth in the deposited silicon film across the substrate surface. In some embodiments, the temperature uniformity of chamber surfaces is adjusted to control and/or minimize precursor deposition on chamber surfaces.

Methods provided herein generally include depositing an ultra-conformal amorphous silicon film onto the surface of a substrate using thermal CVD with a polysilane gas, then treating the film with a plasma formed of a nitrogen precursor gas to convert the deposited amorphous silicon film to a silicon nitride film. Typically, the amorphous silicon deposition and the plasma treatment are performed in the same processing chamber, such as processing chamber mounted to a Producer or Precision platform available from Applied Materials, Inc., located in Santa Clara, Calif. Herein, the processing chamber is configured to process one substrate at a time.

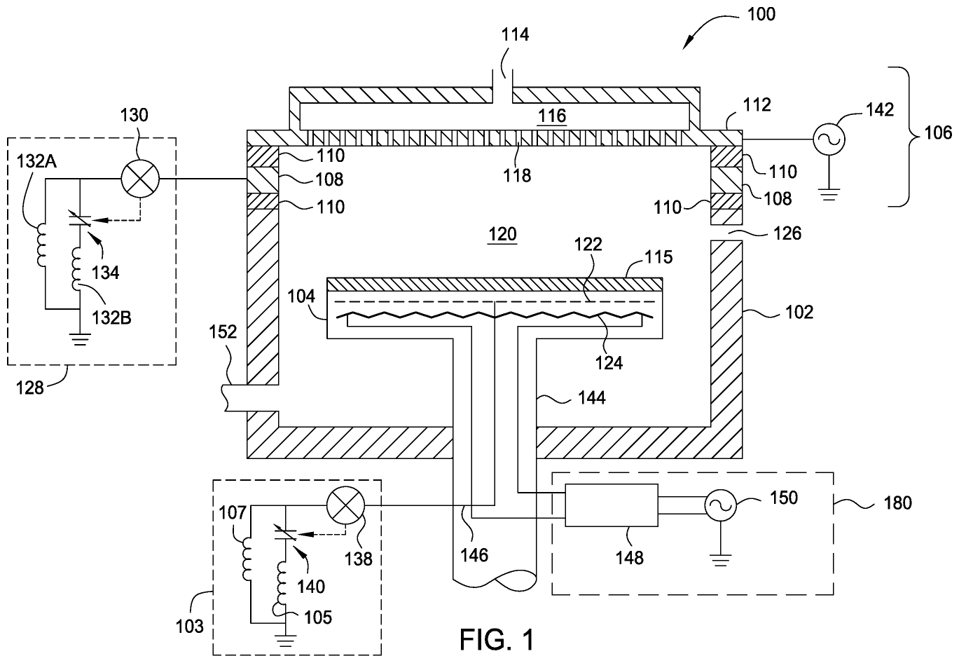

FIG. 1 is a schematic cross-sectional view of an example of a processing chamber 100 used to practice the methods described herein. In the embodiment described, the processing chamber 100 is configured to process a single substrate at a time. The processing chamber 100 features a chamber body 102; a substrate support 104 disposed inside the chamber body 102, and a lid assembly 106 coupled to the chamber body 102 and enclosing the substrate support 104 in a processing volume 120. The substrate 115 is loaded into the processing volume 120 through an opening 126 in a side wall of the chamber body 102, which is conventionally sealed during substrate processing with a door or valve (not shown).

A first electrode 108 is disposed on the chamber body 102 and separates the chamber body 102 from other components of the lid assembly 106. Herein, the first electrode 108 is part of the lid assembly 106. Alternatively, the first electrode 108 is a separate side wall electrode mounted to the interior of, and electrically isolated from, the chamber body 102. Herein, the first electrode 108 is an annular, i.e., a ring-like member, for example a ring electrode. In some embodiments, the first electrode 108 forms a continuous conductive loop around the circumference of the processing volume 120. In other embodiments, the first electrode 108 is discontinuous at desired selected locations. In some embodiments, the first electrode 108 is a perforated electrode, such as a perforated ring or a mesh electrode. In other embodiments, the first electrode 108 is a plate electrode, for example also configured as a secondary gas distributor.

An isolator 110, formed of a dielectric material such as a ceramic or metal oxide, for example aluminum oxide and/or aluminum nitride, contacts the first electrode 108 and separates the first electrode 108 electrically and thermally from an overlying gas distributor 112 and from the chamber body 102.

The gas distributor 112 features openings 118 for admitting process gas into the processing volume 120. The gas distributor 112 herein is coupled to a source of electric power 142, such as an RF generator. At least one of DC power, pulsed DC power, and pulsed RF power may also be used. Herein, the gas distributor 112 is an electrically conductive gas distributor. In other embodiments, the gas distributor 112 is a non-electrically conductive gas distributor where power is not required to be applied thereto. In some other embodiments, the gas distributor 112 is made of both electrically conductive and non-conductive components. For example, the body of the gas distributor 112 is conductive while a face plate of the gas distributor 112 is non-conductive. Additionally, the gas distributor 112 of the chamber is powered, as shown in FIG. 1, or alternatively the gas distributor 112 is coupled to ground if another chamber component is powered to provide the energy source to strike and maintain a plasma in the processing chamber 100.

The first electrode 108 is coupled to a first tuning circuit 128 located between electrical ground and the first electrode 108. The first tuning circuit 128 comprises a first electronic sensor 130 and a first electronic controller 134, which herein is a variable capacitor. Herein, the first tuning circuit 128 is an LLC circuit comprising one or more first tuning circuit inductors 132A and 132B. Additionally, the first tuning circuit 128 may be any circuit that features a variable or controllable impedance under the plasma conditions present in the processing volume 120 during processing. In the embodiment of FIG. 1, the first tuning circuit 128 features a first tuning circuit first inductor 132A in parallel with the first electronic controller 134 in series with a first tuning circuit second inductor 132B. The first electronic sensor 130 herein is a voltage or current sensor, and is coupled to the first electronic controller 134 to afford a degree of closed-loop control of plasma conditions inside the processing volume 120.

A second electrode 122 is coupled to the substrate support 104. The second electrode 122 is embedded within the substrate support 104 or coupled to a surface of the substrate support 104. The second electrode 122 is a plate, a perforated plate, a mesh, a wire screen, or any other distributed arrangement. The second electrode 122 is a tuning electrode, and is coupled to a second tuning circuit 103 by a conduit 146, for example a cable having a selected resistance such as 50Ω, disposed in a shaft 144 of the substrate support 104. The second tuning circuit 103 includes a second electronic sensor 138 and a second electronic controller 140, which, in some embodiments, is a second variable capacitor. In this embodiment, the second tuning circuit 103 includes a first inductor 105 in series with the second electronic controller 140, and a second inductor 107 in parallel with the second electronic controller 140. Typically, the characteristics of the second tuning circuit 103 are adjusted by selecting a variable capacitor that results in an impedance range useful in connection with the characteristics of the plasma and by selecting inductors to modify the impedance range available. Herein, the second electronic sensor 138 is one of a voltage or current sensor, and is coupled to the second electronic controller 140 to provide further control over plasma conditions in the processing volume 120.

A third electrode 124, which functions as at least one of a bias electrode or an electrostatic chucking electrode, is present on or in the substrate support 104. The third electrode is coupled to a second source of electric power 150 through a filter 148, which herein is an impedance matching circuit. The second source of electric power 150 is DC power, pulsed DC power, RF power, pulsed RF power, or a combination thereof.

The electronic controllers 134 and 140 and electronic sensors 130 and 138 coupled to the processing chamber 100 afford real-time control of plasma conditions in the processing volume 120. A substrate 115 is disposed on the substrate support 104, and process gases are flowed through the lid assembly 106 using an inlet 114 according to any desired flow plan. Gases exit the processing chamber 100 through an outlet 152. Electric power is coupled to the gas distributor 112 to establish a plasma in the processing volume 120. In one embodiment, the substrate 115 is subjected to an electrical bias by charging the third electrode 124 to create a negative bias on the substrate support 104 and and/or the substrate 115.

Upon energizing the plasma in the processing volume 120, a first potential difference is established between the plasma and the first electrode 108. A second potential difference is established between the plasma and the second electrode 122. The electronic controllers 134 and 140 are used to adjust the impedance of the ground paths represented by the two tuning circuits 128 and 103. A set point is delivered to the first tuning circuit 128 and the second tuning circuit 103 to provide independent control of deposition rate of a layer onto the substrate and of plasma density uniformity from center to edge of the substrate. In embodiments where the electronic controllers 134 and 140 are both variable capacitors, the electronic sensors 130 and 138 are used by the controllers to detect values to adjust the variable capacitors in order to independently maximize deposition rate and minimize thickness non-uniformity.

Each of the tuning circuits 128 and 103 has a variable impedance that is adjusted using the respective electronic controllers 134 and 140. Where the electronic controllers 134 and 140 are variable capacitors, the capacitance range of each of the variable capacitors, and the inductances of the first tuning circuit inductors 132A and 132B, are chosen to provide an impedance range, depending on the frequency and voltage characteristics of the plasma, that has a minimum in the capacitance range of each variable capacitor. Thus, when the capacitance of the first electronic controller 134 is at a minimum or maximum, impedance of the first tuning circuit 128 is high, resulting in a plasma that has a minimum areal coverage over the substrate support 104. When the capacitance of the first electronic controller 134 approaches a value that minimizes the impedance of the first tuning circuit 128, the areal coverage of the plasma grows to a maximum, effectively covering the entire working area of the substrate support 104. As the capacitance of the first electronic controller 134 deviates from the minimum impedance setting, the plasma shrinks from the chamber walls and the areal coverage of the plasma over the substrate 115 on the substrate support 104 declines. The second electronic controller 140 has a similar effect, increasing and decreasing areal coverage of the plasma over the substrate 115 on the substrate support 104 as the capacitance of the second electronic controller 140 is changed.

The electronic sensors 130 and 138 are used to tune the respective tuning circuits 128 and 103 in a closed loop manner. A set point for current or voltage, depending on the type of sensor used, is installed in each sensor, and the sensor is provided with control software that determines an adjustment to each respective electronic controller 134 and 140 to minimize deviation from the set point. In this way, the coverage of the plasma is selected and dynamically controlled during processing. It should be noted that, while the foregoing discussion is based on the use of electronic controllers 134 and 140 that are variable capacitors, any electronic component with adjustable characteristic capable of changing the areal coverage of the plasma may be used to provide tuning circuits 128 and 103 with adjustable impedance.

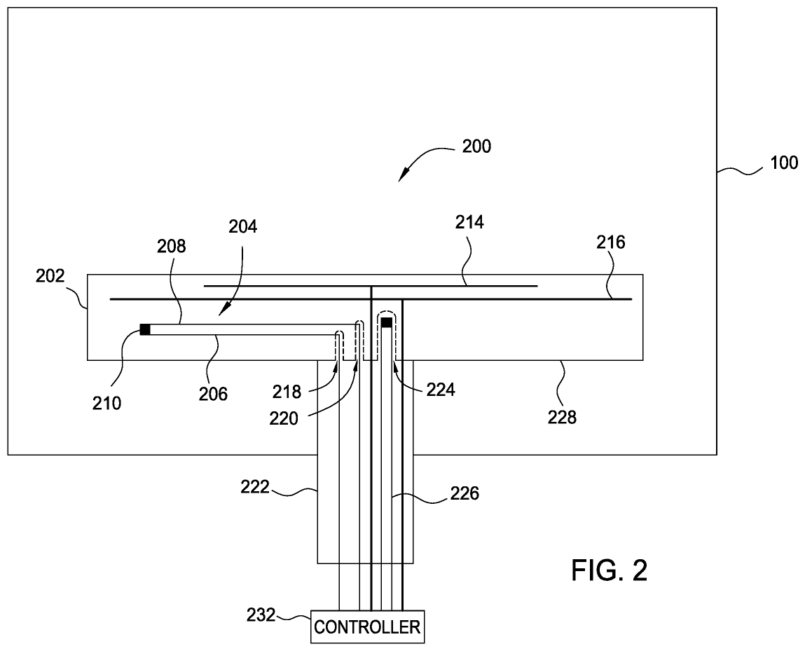

FIG. 2 is a schematic cross-sectional section view of another embodiment of a substrate support 202 for use in processing chamber 100. Substrate support 202 may be used in place of substrate support 104 (shown in FIG. 1), or the features of substrate support 202 may be combined with the features of substrate support 104. Substrate support 202 features a multi-zone heater that is used with the methods disclosed herein to control the surface temperature profile of substrate disposed on the substrate support 202. Typically, the substrate support 202 has an embedded thermocouple 204 and two or more embedded heating elements, such as a first heating element 214 and a second heating element 216.

In some embodiments, the thermocouple 204 includes a first longitudinal piece 206 of a first material and a second longitudinal piece 208 of a second material. The first material and the second material typically have a difference in Seebeck coefficients sufficient to generate a voltage signal corresponding to small temperature variations and a coefficient of thermal expansion close to that of the substrate support material so that neither the thermocouple 204 nor the substrate support 202 is damaged by thermal stresses during temperature cycles.

The first longitudinal piece 206 and the second longitudinal piece 208 are configured as bars, strips, or any other practicable configuration that can both extend radially from the center of the substrate support 202 to an outer heating zone of the substrate support 202 and also have sufficient surface area at both ends to allow formation of a reliable electrical connection therebetween. At the junction end 210 of the longitudinal pieces 206 and 208, the longitudinal pieces 206 and 208 are welded, or otherwise connected using a conductive filler material.

Note that although the longitudinal pieces 206 and 208 shown in FIG. 2 are disposed one over the other, in other embodiments, the longitudinal pieces 206 and 208 may be spaced side by side in the same plane and at the same vertical position within the substrate support 202. Connectors (e.g., conductive wires), not shown, are coupled to the longitudinal pieces 206 and 208. For a dual-zone support, connector connection points are proximate to a conventional thermocouple 226 used to measure the temperature of an inner zone and which is disposed at the center of the substrate support 202.

For a dual-zone support, the connector connection points are proximate to a conventional thermocouple 226 used to measure the temperature of the inner zone and which is disposed at the center of the substrate support 202. Assuming the temperature of the connection points is the same as the temperature of the inner zone, the temperature at the junction end 210 location can be calculated.

A shaft 222 is coupled to the center of the lower surface 228 of the substrate support 202. The shaft 222, houses the connectors to the longitudinal pieces 206 and 208, a connector to the conventional thermocouple 226, and connectors to the heating elements 214 and 216.

The connectors from the thermocouples 226 and 204, and the heating elements 214 and 216, are coupled to a controller 232 that includes a processor and appropriate circuitry adapted to both receive and record signals from the thermocouples 226 and 204, and apply current to the heating elements 214 and 216. In some embodiments, the multi-zone support 200 is disposed in the processing chamber 100 and includes bias electrodes and tuning electrodes as described above with reference to FIG. 1.

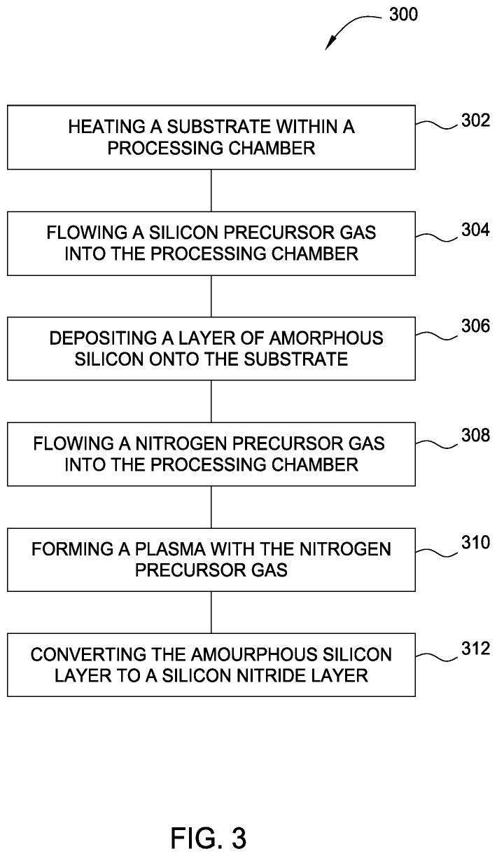

FIG. 3 is a flow diagram outlining a method 300 for depositing a silicon nitride film, according to one embodiment. At activity 302 of the method the 300 a substrate, disposed on a substrate support in a CVD substrate processing chamber, is heated to an average substrate temperature. Herein, the substrate temperature is desirably maintained at between about 300° C. and about 700° C., such as less than about 500° C., for example about 400° C. In some embodiments, a temperature profile is established across the substrate by heating different parts of the substrate at different heating rates and/or to different temperatures, for example using a zoned heater. In some embodiments, a two-zone heater is used and a temperature offset between the zones is about +/−50° C. Different temperature zones having different temperatures may be used to maintain a more uniform temperature over the surface of the substrate.

In some embodiments, a face plate temperature is selected and controlled. Herein, the face plate is a surface of the chamber lid, for example where a gas distributor 112 is used, the inner surface thereof which is exposed to the processing environment and faces the substrate support. Controlling the face plate temperature promotes thermal uniformity in the processing region of the portion of the chamber near the face plate, and improves thermal uniformity of the silicon precursor gas as it exits the face plate (gas distributor 112) into the processing region. In one embodiment, the face plate temperature is controlled by thermally coupling a heating element thereto. This is accomplished by direct contact between the heating element and the face plate, or it can be accomplished by heat conduction through another member. In some embodiments, the face plate temperature is desirably maintained at a selected setpoint between about 100° C. and about 300° C.

At activity 304 of the method 300, a silicon precursor gas is flowed into the chamber through the temperature controlled face plate (gas distributor 112). Herein, the silicon precursor gas is a halogen free polysilane gas such as disilane, trisilane, tetrasilane, or combinations thereof. The polysilane gas is selected based on a thermal budget of the device being formed on the substrate, with tetrasilane having a thermal decomposition temperature that is lower than the thermal decomposition temperature of trisilane which, in turn, has a lower thermal decomposition temperature than disilane. The heated substrate is exposed to the silicon precursor gas and a layer of ultra-conformal amorphous silicon film is deposited thereon. To achieve the ultra-conformal condition, the conformality and pattern loading of the amorphous silicon film is controlled by adjusting precursor gas flow rate, process pressure, spacing between the substrate and the upper electrode, and process temperature. Typically, the precursor gas is provided at a setpoint flow rate between about 20 sccm and about 1000 sccm for a chamber sized for a 300 mm substrate, appropriate scaling may be used for chambers sized for other substrates. Chamber operating pressure is set between about 5 Torr and about 600 Torr. Spacing between the face plate and the substrate is between set at a spacing between about 200 mils (thousandths of an inch) and 2000 mils.

At activity 306 of the method 300, the amorphous silicon layer is deposited on the substrate. Herein, the amorphous silicon layer is between about 5 Å and 30 Å thick, such as about 20 Å thick. By appropriately adjusting the precursor gas flow rate, the process pressure, the spacing between the substrate and the upper electrode, and the process temperature, the deposited silicon layer has a desirable thickness uniformity of less than about 2%. In some embodiments, the thickness of the resulting deposited silicon layer varies from an average value by no more than 2%. In another embodiment, a standard deviation of the thickness of the deposited silicon layer is no more than about 2%. Uniform thickness of the deposited silicon layer allows for complete, or close to complete, nitridation of the deposited silicon layer to its full depth while avoided nitrogen diffusion into the substrate.

At activity 308 of the method 300, a nitrogen precursor gas such as N₂, NH₃, or H₂N₂, a substituted variant thereof, or a combination thereof, is provided to the chamber at a fixed flow rate between about 20 sccm and about 1000 sccm.

At activity 310 of the method 300, a plasma is formed of the nitrogen precursor gas in the chamber. The plasma is formed by capacitive or inductive coupling of the power source to the nitrogen precursor gas, energized by coupling RF power into the precursor gas or gas mixture. The RF power herein is a dual-frequency RF power that has a high frequency component and a low frequency component. The RF power is applied at a power level between about 100 W and about 2,000 W. The RF power frequency set point is between about 350 kHz to about 60 MHz. The RF power frequency may be all high-frequency RF power, for example at a frequency of about 13.56 MHz, or may be a mixture of high-frequency power and low frequency power, for example an additional frequency component at about 300 kHz.

In some embodiments, nitridation depth uniformity across the substrate is enhanced by adjusting the plasma density profile. The plasma density profile is adjusted by biasing a first electrode coupled to a side wall of the chamber and/or second electrode coupled to the substrate support. Each electrode is typically controlled to provide the impedance needed for a desired current to flow through the electrode. A resonant tuning circuit is typically coupled to each electrode and to ground, and components for the resonant tuning circuit are selected, with at least one variable component, so the impedance can be adjusted dynamically to maintain the desired current flow. The current flow through each electrode is desirably maintained at a set point between about 0 amps (A) and about 30 Å or between about 1 Å and about 30 Å.

In another embodiment, a third electrode, which is a bias electrode and/or an electrostatic chucking electrode, is coupled to the substrate support. The third electrode is coupled to a second source of electric power through a filter 148, which is an impedance matching circuit. The second source of electric power may be DC power, pulsed DC power, RF power, pulsed RF power, or a combination thereof.

In another embodiment, nitridation depth uniformity across the substrate is further enhanced by controlling the temperature of the chamber surfaces exposed to the plasma. When the chamber surfaces are allowed to thermally float, hot and cold spots can develop that affect plasma density and precursor reactivity in uncontrolled ways. As described above, the face plate of the gas distributor 112 is heated using a resistive heater or thermal fluid disposed in a conduit through a portion of the face plate or otherwise in direct contact or thermal contact with the face plate. The conduit is disposed through an edge portion of the face plate to avoid disturbing the gas flow function of the face plate. Heating the edge portion of the face plate is useful to reduce the tendency of the face plate edge portion to be a heat sink within the chamber.

The chamber walls may also be, or alternatively be, heated to a similar effect. Heating the chamber surfaces exposed to the plasma also minimizes deposition and condensation on, or reverse sublimation from, the chamber surfaces thereby reducing the cleaning frequency of the chamber and increasing the mean number of process cycles per cleaning of the chamber. Higher temperature surfaces also promote dense deposition that is less likely to produce particles that fall therefrom onto a substrate. Thermal control conduits with resistive heaters and/or thermal fluids may be disposed through the chamber walls to achieve thermal control of the chamber walls.

At activity 312 of the method 300, the deposited amorphous silicon film is exposed to the nitrogen plasma to convert the deposited amorphous silicon film to a silicon nitride film. The treatment time is between about 30 seconds (s) to about 300 s. Longer treatment times at higher power or using RF/DC bias will convert the amorphous silicon film to a stoichiometric silicon nitride film.

The methods described herein can be used to produce silicon nitride film layers of about 5 Å to about 30 Å, such as about 20 Å. The method can be repeated multiple times to produce thicker, multilayer, silicon nitride films, such as films of about 100 Å to about 150 Å. It is expected that the amorphous silicon film will undergo a volume expansion on conversion to silicon nitride, this phenomenon can be potentially used to gap-fill narrow trenches.

Benefits of the disclosure include a highly uniform thickness and composition of a silicon nitride film, formed without generating hydrochloric acid or ammonium chloride byproducts. In addition, the methods disclosed herein produce hermetic silicon nitride films that are resistant to oxidation, such as from high temperature annealing processes.

While the foregoing is directed to embodiments of the present disclosure, other and further embodiments of the disclosure may be devised without departing from the basic scope thereof, and the scope thereof is determined by the claims that follow.

1. A method of forming a film layer comprising:
heating a substrate to a substrate temperature within a substrate processing chamber;
flowing a silicon precursor gas into the substrate processing chamber;
depositing a layer of amorphous silicon on the substrate;
flowing a nitrogen precursor gas into the substrate processing chamber;
forming a plasma within the substrate processing chamber with the nitrogen precursor gas; and
exposing the deposited amorphous silicon layer to the plasma to convert at least a portion of the deposited amorphous silicon layer to a silicon nitride layer.

2. The method of claim 1, wherein the silicon precursor gas comprises disilane, trisilane, tetrasilane, or a combination thereof.

3. The method of claim 1, wherein the nitrogen precursor gas comprises N₂, NH₃, H₂N₂, or a combination thereof, and wherein the silicon nitride layer comprises a hermetic stoichiometric nitride film.

4. The method of claim 1, wherein the thickness of the silicon nitride layer is between about 5 Å and about 30 Å.

5. The method of claim 1, wherein the substrate temperature is between about 300° C. and 700° C.

6. The method of claim 1, wherein heating the substrate comprises heating a first portion of the substrate to a first temperature and heating a second portion of the substrate to a second temperature, wherein the offset between the first temperature and the second temperature is between about +/−10° C. and about +/−50° C.

7. The method of claim 1, further comprising heating a plate facing the substrate to a temperature between about 100° C. and about 300° C.

8. The method of claim 7, wherein the silicon precursor gas flows through the plate.

9. The method of claim 1, further comprising biasing an electrode coupled to a side wall of the chamber, wherein the electrode is coupled to a resonant tuning circuit, and wherein the current flow through the electrode is desirably maintained at between about 1 amp and 30 amps.

10. The method of claim 6, further comprising biasing a first electrode coupled to the substrate support, wherein the electrode is coupled to a resonant tuning circuit, and wherein the current flow through the electrode is desirably maintained between about 1 amp and 30 amps.

11. The method of claim 9, further comprising dynamically adjusting an impedance of the resonant tuning circuit to control the current flow.

12. The method of claim 10, further comprising dynamically adjusting an impedance of the resonant tuning circuit to control the current flow.

13. The method of claim 12, further comprising biasing a second electrode coupled to the substrate support, wherein the second electrode is coupled to an impedance matching circuit.

14. A method of forming a film layer comprising:
heating a substrate, disposed on a substrate support, to a temperature of below about 500° C. within a substrate processing chamber;
flowing a silicon precursor gas into the substrate processing chamber;
depositing a layer of amorphous silicon on the substrate;
flowing a nitrogen precursor gas into the substrate processing chamber, wherein the nitrogen precursor gas comprises N₂, NH₃, H₂N₂, or a combination thereof;
forming a plasma of the nitrogen precursor gas within the substrate processing chamber;
biasing a first electrode coupled to the substrate support, wherein the first electrode is coupled to a first resonant tuning circuit;
dynamically adjusting the impedance of the first resonant tuning circuit to control the current flow through the first electrode, wherein the current flow is desirably maintained at a set point between about 1 amp and 30 amps; and
nitriding the deposited amorphous silicon layer to convert the deposited amorphous silicon layer to a silicon nitride layer.

15. A method of forming a film layer comprising:
heating a substrate to a substrate temperature of below about 500° C. comprising heating a first portion of the substrate to a first temperature and heating a second portion of the substrate to a second temperature, wherein the offset between the first temperature and the second temperature is between about +/−10° C. and about +/−50° C.,
flowing a silicon precursor gas into a substrate processing chamber;
depositing a film of amorphous silicon on the substrate of between about 5 Å and about 30 Å;
flowing a nitrogen precursor gas into the substrate processing chamber, wherein the nitrogen precursor gas comprises N₂, NH₃, H₂N₂, or a combination thereof;
forming a plasma with the nitrogen precursor gas, wherein the plasma is formed within the processing chamber;
biasing a first electrode coupled to a substrate support, wherein the first electrode is coupled to a first resonant tuning circuit;
dynamically adjusting the impedance of the first resonant tuning circuit to control the current flow through the first electrode, wherein the current flow is desirably maintained at a set point between about 1 amp and 30 amps;
biasing a second electrode coupled to a side wall of the chamber, wherein the second electrode is coupled to a second resonant tuning circuit;
dynamically adjusting the impedance of the second resonant tuning circuit to control the current flow through the second electrode, wherein the current flow is desirably maintained at a set point between about 1 amp and 30 amps; and
converting the deposited amorphous silicon film to a hermetic stoichiometric silicon nitride film.

16. The method of claim 14, further comprising:
biasing a second electrode coupled to a side wall of the substrate processing chamber, wherein the second electrode is coupled to a second resonant tuning circuit; and
dynamically adjusting the impedance of the second resonant tuning circuit to control the current flow through the second electrode, wherein the current flow is desirably maintained at a set point between about 1 amp and 30 amps.

17. The method of claim 14, further comprising:
biasing a third electrode coupled to the substrate support, wherein the third electrode is coupled to an impedance matching circuit, and wherein the third electrode is coupled to a power source that is a DC power, pulsed DC power, RF power, pulsed RF power, or a combination thereof.

18. The method of claim 14, wherein heating the substrate comprises heating a first portion of the substrate to a first temperature and heating a second portion of the substrate to a second temperature, wherein the offset between the first temperature and the second temperature is between about +/−10° C. and about +/−50° C.

19. The method of claim 14, wherein the silicon nitride layer is a hermetic stoichiometric nitride film.

20. The method of claim 14, wherein a thickness of the silicon nitride layer is between about 5 Å and about 30 Å.
